(19) United States
(12) Patent Application Publication
(10) Pub. No.: US 2025/0239575 A1
(43) Pub. Date: Jul. 24, 2025

(54) SEMICONDUCTOR PACKAGE

(71) Applicant: Samsung Electronics Co., Ltd., Suwon-si (KR)

(72) Inventors: Seulgi YU, Suwon-si (KR); Sangsub SONG, Suwon-si (KR); Seokbeom YONG, Suwon-si (KR)

(73) Assignee: Samsung Electronics Co., Ltd., Suwon-si (KR)

(21) Appl. No.: 18/811,960

(22) Filed: Aug. 22, 2024

(30) Foreign Application Priority Data
Jan. 23, 2024 (KR) 10-2024-0010406

(51) Int. Cl. H01L 25/16; H01L 23/00; H01L 23/31; H01L 23/498; H01L 23/538; H01L 29/92; H10B 80/00

(52) U.S. Cl. CPC H01L 25/162; H01L 23/5385; H10D 1/62; H01L 23/3107; H01L 23/49811; H01L 24/16; H01L 24/32; H01L 24/73; H01L 2224/16227; H01L 2224/32225; H01L 2224/73253; H10B 80/00

(57) ABSTRACT

Described is a semiconductor package for addressing reliability issues of packages and improving power integrity (PI) characteristics of logic chips. The semiconductor package may include a package substrate, an interposer on the package substrate and including a body layer and a redistribution layer, a semiconductor-bridge in the interposer and including a decoupling capacitor, a first semiconductor device on a central portion of a top surface of the interposer, and a second semiconductor device on an outer portion of the top surface of the interposer and adjacent to the first semiconductor device, wherein the decoupling capacitor is connected to the first semiconductor device by the redistribution layer.

### CROSS-REFERENCE TO RELATED APPLICATION

This application is based on and claims priority under 35 U.S.C. § 119 to Korean Patent Application No. 10-2024-0010406, filed on Jan. 23, 2024, in the Korean Intellectual Property Office, the disclosure of which is incorporated by reference herein in its entirety.

### BACKGROUND

Inventive concepts relate to a semiconductor package, for example to a semiconductor package including a silicon (Si)-bridge.

With the development of the electronics industry, demands for high-functional, high-speed, and miniaturized electronic components are increasing. Accordingly, the need or desire for smaller and multi-functional semiconductor chips used in electronic components is increasing. Additionally, in the semiconductor package field, the size of semiconductor package is being miniaturized based on small semiconductor chips. Additionally, due to the demands for improved performance and reduced form factor of semiconductor packages, semiconductor package structures are moving towards multi-chip integrated structures. The multi-chip integration may, for example, refer to integrating chips manufactured in different processes together within a single semiconductor package.

### SUMMARY

Inventive concepts relate to a semiconductor package for addressing reliability issues related to semiconductor packages and for improving the power integrity (PI) characteristics of, for example, logic chips.

In addition, inventive concepts are not limited to the above-mentioned concepts, and other inventive concepts and aspects thereof may be clearly understood by those ordinarily skilled in the art from the description below.

According to some example embodiments of inventive concepts, a semiconductor package may include a package substrate, an interposer on the package substrate and including a body layer and a redistribution layer, a semiconductor-bridge in the interposer and including a decoupling capacitor, a first semiconductor device on a central portion of a top surface of the interposer, and a second semiconductor device on an outer portion of the top surface of the interposer and adjacent to the first semiconductor device, wherein the decoupling capacitor is connected to the first semiconductor device by the redistribution layer.

According to some example embodiments of inventive concepts, a semiconductor package may include a package substrate, a panel level package (PLP) interposer on the package substrate and including a body layer and a redistribution layer, a silicon (Si)-bridge in the PLP interposer and comprising at least one decoupling capacitor, a logic chip on a central portion of a top surface of the PLP interposer, and at least two high bandwidth memory (HBM) packages on an outer portion of the top surface of the PLP interposer and adjacent to sides of the logic chip in a first direction, wherein the at least decoupling capacitor is connected to the logic chip by the redistribution layer and a connection terminal, the redistribution layer extending in the first direction and the connection terminal in a central portion of the logic chip in the first direction.

According to some example embodiments of inventive concepts, a semiconductor package may include a package substrate, a Si-bridge in or on the package substrate and including a decoupling capacitor, a logic chip on a central portion of the package substrate, and an HBM package on an outer portion of the package substrate and adjacent to the logic chip in a first direction, wherein the decoupling capacitor is connected to the logic chip by a wiring layer of the package substrate or a redistribution layer on the package substrate.

### BRIEF DESCRIPTION OF THE DRAWINGS

Example embodiments will be more clearly understood from the following detailed description taken in conjunction with the accompanying drawings in which:

FIGS. 1A and 1B are a perspective view and a cross-sectional view of a semiconductor package, respectively, according to some example embodiments;

FIG. 1C is a detailed cross-sectional view of a high bandwidth memory (HBM) package of the semiconductor package of FIG. 1B;

FIG. 1D is a schematic circuit diagram showing the impedance on a power path from a power management integrated circuit (PMIC) to a logic chip in the semiconductor package of FIG. 1B;

FIG. 2 is a cross-sectional view of a semiconductor package according to a comparative example;

FIG. 3A is a cross-sectional view of a semiconductor package according to some example embodiments;

FIG. 3B is a schematic cross-sectional view showing the impedance on a power path from a PMIC to a logic chip in the semiconductor package of FIG. 3A;

FIG. 4 is a cross-sectional view of a semiconductor package according to some example embodiment;

FIGS. 5A to 5C are cross-sectional views of a semiconductor package according to some example embodiments; and

FIG. 6 is a cross-sectional view of a semiconductor package according to some example embodiments.

### DETAILED DESCRIPTION OF EXAMPLE EMBODIMENTS

Hereinafter, example embodiments are described in detail with reference to the attached drawings. The same reference numerals are used for the same components in the drawings, and duplicate descriptions thereof are omitted.

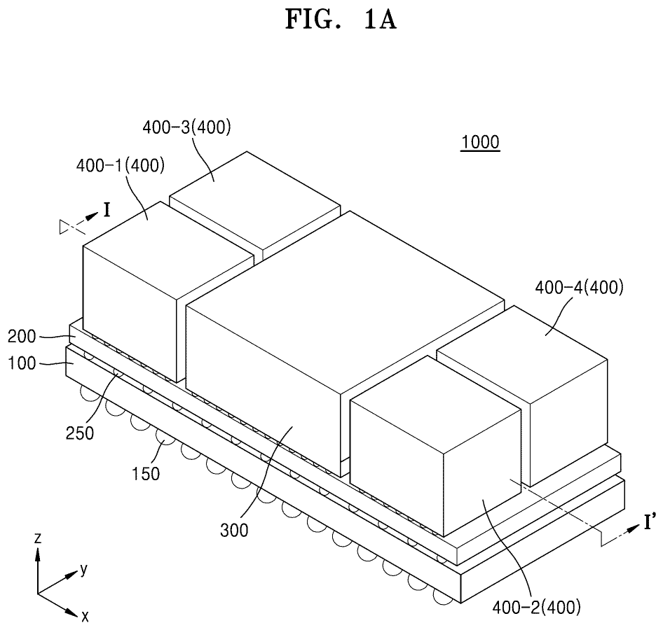

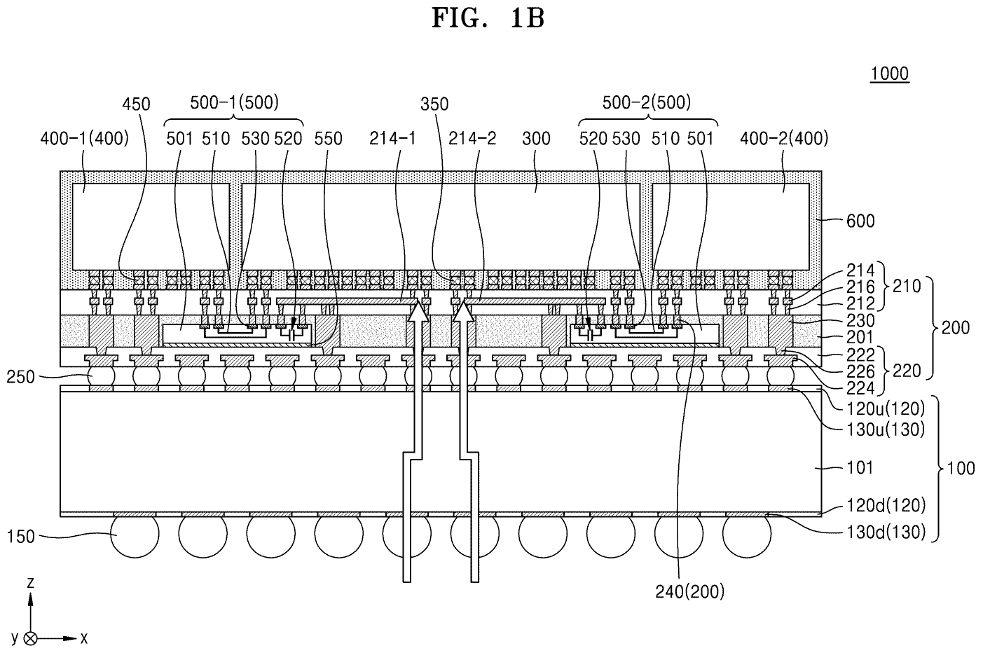

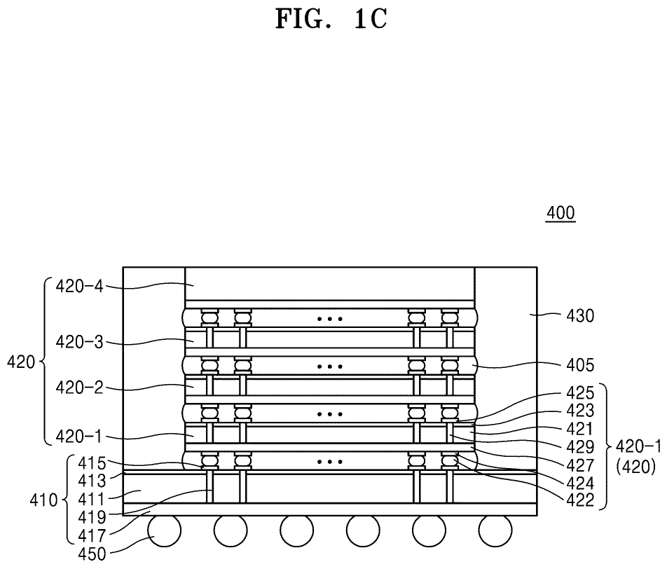

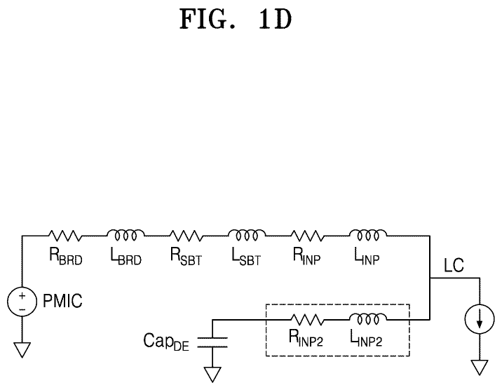

FIGS. 1A and 1B are a perspective view and a cross-sectional view of a semiconductor package, respectively, according to some example embodiments, FIG. 1C is a detailed cross-sectional view of a high bandwidth memory (HBM) package of the semiconductor package of FIG. 1B, and FIG. 1D is a schematic circuit diagram showing the impedance on a power path from a power management integrated circuit (PMIC) to a logic chip in the semiconductor package of FIG. 1B.

Referring to FIGS. 1A to 1D, a semiconductor package 1000 according to some example embodiments may include a package substrate 100, an interposer 200, a first semiconductor device 300, second semiconductor devices 400, semiconductor-bridges 500, and a sealant 600.

The package substrate 100 may include, for example, a ceramic substrate, a printed circuit board (PCB), an organic substrate, an interposer substrate, and/or the like. In some example embodiments, the package substrate 100 may include, for example, an active wafer, such as a silicon wafer, but example embodiments are not limited thereto. In the semiconductor package 1000 according to some example embodiments, the package substrate 100 may include a PCB. However, the package substrate 100 is not limited to a PCB.

The package substrate 100 may include a substrate body layer 101, protective layers 120, and substrate pads 130. The substrate body layer 101 may constitute a body of the package substrate 100 and may include one or more wiring layer therein. For example, when the package substrate 100 is a PCB, the substrate body layer 101 may include, for example, a core layer and/or a wiring layer, but example embodiments are not limited thereto.

The core layer may include, for example, glass fiber and/or resin, such as, for example, FR4. In addition, or alternatively, the core layer may include, for example, bismaleimide-triazine (BT) resin, polycarbonate (PC) resin, build-up films, such as Ajinomoto build-up film (ABF), and/or other laminate resin. In some example embodiments, the core layer may be omitted.

The wiring layer may be divided into an upper wiring layer and a lower wiring layer based on the core layer. The upper wiring layer and the lower wiring layer may each include multiple layers of wires. The number of layers of wires in the upper wiring layer may be the same as or different from those in the lower wiring layer. In the semiconductor package 1000 according to some example embodiments, the wiring layer may include, for example, 8 to 14 layers of wires. However, the number of layers of wires in the wiring layer is not limited to the above numerical range.

The wiring layer may include multiple layers of wires, an interlayer insulating layer that insulates the wires from each other, and/or a vertical via that connects the wires to each other. The wires and the vertical via may include, for example, copper (Cu). However, the material of the wires and the vertical via is not limited to Cu. The interlayer insulating layer may include, for example, pre-preg (PPG). However, I material of the interlayer insulating layer is not limited to a PPG.

In some example embodiments, the package substrate 100 may be or include a redistribution substrate. In such a case, the substrate body layer 101, for example, may not include a separate core layer and may include multiple layers of wires and an interlayer insulating layer of photo-imageable dielectric (PID) resin, but example embodiments are not limited thereto.

The protective layers 120 may include an upper protective layer 120u on a top surface of the substrate body layer 101 and a lower protective layer 120d on a bottom surface of the substrate body layer 101. The protective layers 120 may include, for example, solder resist (SR). However, the material of the protective layers 120 is not limited to SR.

The substrate pads 130 may include an upper substrate pad 130u on the top surface of the substrate body layer 101 and a lower substrate pad 130d on the bottom surface of the substrate body layer 101. The upper substrate pad 130u may penetrate the upper protective layer 120u. In addition, the lower substrate pad 130d may penetrate (for example extend within or at least partially extend within) the lower protective layer 120d. Each of the upper substrate pad 130u and the lower substrate pad 130d may be connected to the wires of the substrate body layer 101. Each of first connection terminals 250 may be disposed on the upper substrate pad 130u, and each of external connection terminals 150 may be disposed on the lower substrate pad 130d. In some embodiments, the substrate pads 130 may be included as part of wires of the wiring layer.

The interposer 200 may be mounted on the package substrate 100 through (for example, by) the first connection terminals 250. The first connection terminals 250 may include, for example, one or more pillars and solder. However, according to some example embodiments, the first connection terminals 250 may include only solder, but example embodiments are not limited thereto.

External connection terminals 150 may connect the semiconductor package 1000 to, for example, a package substrate of an external system or a main board of an electronic device, such as, for example, a mobile device. The external connection terminals 150 may include, for example at least one conductive material, for example, at least one of solder, tin (Sn), silver (Ag), Cu, aluminum (Al), or any alloy thereof. However, the material of the external connection terminals 150 is not limited thereto.

The interposer 200 may be positioned between, for example vertically between, the package substrate 100 and the semiconductor devices 300 and 400. For example, the semiconductor devices 300 and 400 may be positioned on the interposer 200, and the interposer 200 may mediate signal transmission between the semiconductor devices 300 and 400 and signal and/or power transmission between the semiconductor devices 300 and 400 and the package substrate 100. In the semiconductor package 1000 according to some example embodiments, the interposer 200 may be, for example, an interposer for a 2.3D package, but example embodiments are not limited thereto. In some example embodiments, the interposer 200 may be referred to as, for example, a panel level package (PLP) interposer, a re-distribution layer (RDL) interposer, or the like.

For reference, an interposer may include an interposer for a 2.5D package and/or an interposer for a 2.3D package. The interposer for a 2.5D package usually refers to a silicon (Si)-interposer and may include a through silicon via (TSV) inside. On the other hand, the interposer for a 2.3D package may refer to an organic or inorganic interposer that does not contain a TSV. The organic interposer may include, for example, a body layer of polyimide (PI), benzocyclobutene (BCB), and polybenzoxazole (PBO), and the inorganic interposer may include a body layer of ceramic and/or glass, but example embodiments are not limited thereto.

In the semiconductor package 1000 according to some example embodiments, the interposer 200 may include a body layer 201, an upper redistribution layer 210, a lower redistribution layer 220, through posts 230, and through electrodes 240. As described above, the body layer 201 may include, for example, an organic or inorganic material.

The upper redistribution layer 210 may be disposed on a top surface of the body layer 201. The upper redistribution layer 210 may be connected to front surfaces, which may be active surfaces, of the semiconductor devices 300 and 400. Accordingly, the upper redistribution layer 210 may be referred to as a frontside redistribution layer.

The upper redistribution layer 210 may include an upper interlayer insulating layer 212, upper redistribution lines 214, and upper vertical vias 216. The upper interlayer insulating layer 212 may include an insulating material, for example, PID or photo-imageable polyimide (PIP) resin and may further include an inorganic filler. However, the material of the upper interlayer insulating layer 212 is not limited thereto. For example, the upper interlayer insulating layer 212 may include polymide isoindro quirazorindione (PIQ), PI, PBO, and the like.

The upper interlayer insulating layer 212 may have, for example, a multi-layer structure according to the multi-layer structure of the upper redistribution lines 214, but example embodiments are not limited thereto. However, in FIG. 1B, for convenience, the upper interlayer insulating layer 212 is shown to have a single-layer structure. When the upper interlayer insulating layer 212 has a multi-layer structure, all layers of the upper inter-layer insulating layer 212 may include a same material and/or at least one layer thereof may include another material.

The upper redistribution lines 214 may be arranged in multiple layers within the upper interlayer insulating layer 212. The upper redistribution lines 214 in different layers may be connected to each other by the upper vertical vias 216. The upper redistribution lines 214 and the upper vertical vias 216 may include, for example, Cu. However, the material of the upper redistribution lines 214 and the upper vertical vias 216 is not limited to Cu. In FIG. 1B, on a top surface of the upper interlayer insulating layer 212, portions connected to second and third connection terminals 350 and 450 may be treated as, for example, referred to as, part of the top redistribution lines 214 or may be referred to as upper redistribution pads separately from the upper redistribution lines 214.

The lower redistribution layer 220 may be disposed on a bottom surface of the body layer 201. The lower redistribution layer 220 may be referred to as a backside redistribution layer. The lower redistribution layer 220 may include a lower interlayer insulating layer 222, a lower redistribution line 224, and a lower vertical via 226. The lower interlayer insulating layer 222, the lower redistribution lines 224, and the lower vertical vias 226 may correspond to or be similar to the upper interlayer insulating layer 212, the upper redistribution lines 214, and the upper vertical vias 216 of the upper redistribution layer 210 described above. In FIG. 1B, on a bottom surface of the lower interlayer insulating layer 222, portions connected to the first connection terminals 250 may be treated as, for example referred to as, part of the lower redistribution lines 224 or may be treated as, for example referred to as, lower redistribution pads separate from the lower vertical vias 226.

The through posts 230 may be positioned between the upper redistribution layer 210 and the lower redistribution layer 220. Since the body layer 201 is positioned between the upper redistribution layer 210 and the lower redistribution layer 220, the through posts 230 may pass through (for example, extend or at least partially extend through) the body layer 201. The through posts 230 may electrically connect the upper redistribution layer 210 to the lower redistribution layer 220. For example, a top surface of the through post 230 may be connected to the upper redistribution line 214 of the upper redistribution layer 210, and a bottom surface of the through post 230 may be connected to the lower redistribution line 224 of the lower redistribution layer 220.

The through posts 230 may include, for example, Cu. Accordingly, the through posts 230 may be referred to as Cu posts. However, the material of the through posts 230 is not limited to Cu. The through post 230 may be formed through, for example, electroplating using a seed metal. The seed metal may include, for example, one or more of various metal materials, such as Cu, titanium (Ti), tantalum (Ta), titanium nitride (TiN), and/or tantalum nitride (TaN) or any alloy thereof. In the semiconductor package 1000 according to some example embodiments, the seed metal may be included in the through posts 230. For example, the seed metal may be formed of or include Cu and the through posts 230 may also be formed of or include Cu. Thus, in FIG. 1B, the seed metal is not shown.

The through electrodes 240 may be positioned between the upper redistribution layer 210 and the semiconductor-bridges 500. Since the body layer 201 may be positioned between the upper redistribution layer 210 and the semiconductor-bridges 500, the through electrodes 240 may penetrate the body layer 201. The through electrodes 240 may electrically connect the semiconductor-bridges 500 to the upper redistribution layer 210. The through electrodes 240 may include, for example, Cu. However, the material of the through electrodes 240 is not limited to Cu.

The first semiconductor device 300 may be mounted on the interposer 200 through (for example, by or by using) the second connection terminals 350. As shown in FIGS. 1A and 1B, the first semiconductor device 300 may be positioned in a central portion of the interposer 200 in an X-direction. However, the position of the first semiconductor device 300 is not limited thereto. For example, the first semiconductor device 300 may be positioned to be biased to either side of the interposer 200 in the X-direction.

The first semiconductor device 300 may include, for example, a logic chip. Accordingly, the first semiconductor device 300 may include a plurality of logic devices therein. A logic device may perform, for example, or one or more of various signal processing function, and may include, for example, an AND, an OR, a NOT, a flip-flop, and the like.

In the semiconductor package 1000 according to some example embodiments, the first semiconductor device 300 may include, for example, an application processor (AP), a microprocessor, a central processing unit (CPU), a graphics processing unit (GPU), a controller, or an application-specific integrated circuit (ASIC), and/or the like, but example embodiments are not limited thereto. Accordingly, the first semiconductor device 300 may be referred to as, for example, an AP chip, a process chip, a controller chip, and/or a CPU chip, depending on its function(s). In addition, or alternatively, in terms of integrated functionality, the first semiconductor device 300 may be referred to as a system on chip (SoC). The first semiconductor device 300 may include devices for supporting communication. However, in some example embodiments, the devices for supporting communication may be separately provided as another chip, e.g., a modem chip, and may be disposed on the interposer 200 in a structure that is coupled to the first semiconductor device 300.

The first semiconductor device 300 may include a substrate and a device layer. The device layer may include an integrated circuit layer and multiple wiring layers. The integrated circuit layer may be formed on an active surface of the substrate. The integrated circuit layer may include a plurality of logic devices. The multiple wiring layers disposed on a bottom surface of the substrate may include multiple layers of wires. A bottom surface of the first semiconductor device 300 may be a front surface thereof, which may be an active surface, and a top surface of the first semiconductor device 300 may be a back surface thereof, which may be an inactive surface. In other words, with respect to the substrate, the bottom surface of the substrate where the multiple wiring layers may arranged may correspond to the front surface of the first semiconductor device 300 and the top surface of the substrate may correspond to the back surface of the first semiconductor device 300.

The second semiconductor devices 400 may be mounted on the interposer 200 through (for example, by using) the third connection terminals 450. As shown in FIGS. 1A and 1B, the second semiconductor devices 400 may be disposed on an outer portion of the interposer 200 in the X-direction. For example, the second semiconductor devices 400 may be positioned adjacent to a side or sides, for example in some example embodiments both sides, of the first semiconductor device 300 in the X-direction. However, the position of the second semiconductor devices 400 is not limited thereto. For example, when the first semiconductor device 300 is biased toward one side in the X-direction, the second semiconductor devices 400 may be biased toward the opposite side in the X-direction.

The second semiconductor device 400 may include, for example, a memory chip or a memory package. The memory chip may include, for example, a volatile memory device, such as dynamic random-access memory (DRAM), static random-access memory (SRAM), and/or the like, or a non-volatile memory device, such as flash memory, and the like. The memory package may have, for example, a package structure in which a plurality of memory chips are stacked.

In the semiconductor package 1000 according to some example embodiments, the second semiconductor device 400 may include, for example, an HBM package as a memory package. However, the second semiconductor device 400 is not limited to an HBM package. For example, the second semiconductor device 400 may have a general package structure as a memory package. For example, the second semiconductor device 400 may include an upper package substrate and a plurality of memory chips stacked on the upper package substrate. In addition, or alternatively, the memory chips may be stacked on the upper package substrate through (for example, by or by using) bonding wires or may be stacked on the upper package substrate through (for example by or by using) bumps and TSVs.

Hereinafter, the second semiconductor device 400, which is an HBM package, is described in more detail with reference to FIG. 1C. The second semiconductor devices 400 may be mounted on the interposer 200 through (for example, by using) the third connection terminals 450. The second semiconductor device 400 may include a base chip 410, a plurality of core chips 420, and an inner sealant 430.

The base chip 410 may be positioned in a lowermost portion of the second semiconductor device 400 and may include a substrate 411, a protective layer 413, upper pads 415, a device layer 417, and through electrodes 419. The substrate 411 may include, for example, at least one semiconductor element, such as Si or germanium (Ge), and/or at least one a compound semiconductor, such as silicon carbide (SiC), gallium arsenide (GaAs), indium arsenide (InAs), and/or indium phosphide (InP). The protective layer 413 may be formed on a top surface of the substrate 411 and may protect the substrate 411. The upper pads 415 may be disposed on the protective layer 413. The device layer 417 may be disposed on a bottom surface of the substrate 411 and may include an integrated circuit layer and a wiring layer. The through electrodes 419 may penetrate (for example, extend or at least partially extend within) the substrate 411 and may connect the upper pads 415 to the wiring layer of the device layer 417.

The base chip 410 may include at least one logic device. For example, the base chip 410 may include logic devices in the integrated circuit layer of the device layer 417. Accordingly, the base chip 410 may be or include a logic chip. The base chip 410 positioned below the core chips 420 may integrate and/or transmit signals from the core chips 420 to the outside and may also transmit signals and/or power from the outside to the core chips 420. Accordingly, the base chip 410 may be referred to as a buffer chip or a control chip.

Each of the core chips 420 may be disposed on the base chip 410 and may include, for example, a memory chip. For example, each of the core chips 420 may be or include, for example, a DRAM chip. Each of the core chips 420 may include a substrate 421, bumps 422, a protective layer 423, chip pads 424, upper pads 425, a device layer 427, and through electrodes 429. The substrate 421, the protective layer 423, the upper pads 425, and the through electrodes 429 may respectively correspond or be similar to the substrate 411, the protection layer 413, the upper pads 415, and the through electrodes 419 of the base chip 410 described above.

The bumps 422 may be respectively disposed on bottom surfaces of chip pads 424. The chip pads 424 may be disposed on a bottom surface of the device layer 427 and may be connected to a wiring layer of the device layer 427. Accordingly, the bumps 422 may be connected to the wiring layer of the device layer 427 through (for example, by) the chip pads 424. The bumps 422 may include, for example, pillars and/or solder, but example embodiments are not limited thereto. For example, in some example embodiments, the bumps 422 may include only solder. For example, DRAM devices may be included in an integrated circuit layer of the device layer 427.

As shown in FIG. 1C, an uppermost core chip 420-4 of the core chips 420 may, for example, not include the through electrodes 429, but example embodiments are not limited thereto. In addition, or alternatively, since through electrodes 419 of the base chip 410 and through electrodes 429 of the core chip 420 may penetrate (for example, extend or at least partially extend through) a silicon substrate, through electrodes 419 and 429 may correspond to TSVs. In addition, any or each of the core chips 420 may be stacked on the base chip 410 or below, for example immediately or directly below, a core chip 420 through (for example, by or by using) the bumps 422 and an adhesive layer 405. In FIG. 1C, four core chips 420 are stacked on the base chip 410, but the number of core chips 220 is not limited to four. For example, three or less, or five or more core chips 420 may be stacked on the base chip 410.

The inner sealant 430 on the base chip 410 may cover the core chips 420. As shown in FIG. 1C, the inner sealant 430 not cover a top surface of the uppermost core chip 420-4. However, in some example embodiments, the inner sealant 430 may cover or at least partially cover the top surface of the uppermost core e 420-4. The inner sealant 430 may include, for example, an epoxy mold compound (EMC). However, the material of the inner sealant 430 is not limited to an EMC.

As shown in FIG. 1A, in the semiconductor package 1000 according to some example embodiments, four second semiconductor devices 400, e.g., HBM packages, may be disposed on the interposer 200. However, the number of second semiconductor devices 400 is not limited to four. For example, three or less or five or more second semiconductor devices 400 may be disposed on the interposer 200.

The semiconductor-bridges 500 may be positioned in the interposer 200. For example, the semiconductor-bridges 500 may be positioned in the body layer 201 of the interposer 200. The semiconductor-bridge 500 may be, for example, a Si-bridge, but example embodiments are not limited thereto. The semiconductor-bridge 500 may be referred to as, for example, a semiconductor-bridge interposer, a Si-bridge interposer, and the like.

The semiconductor-bridges 500 may connect the first semiconductor device 300 to the second semiconductor devices 400. Accordingly, the semiconductor-bridges 500 may be positioned in the interposer 200 at corresponding positions between the first semiconductor device 300 and the second semiconductor devices 400. In addition, the semiconductor-bridges 500 may overlap with (for example, at least partially overlap with) a portion of the first semiconductor device 300 and a portion of the second semiconductor device 400.

In the semiconductor package 1000 according to some example embodiments, the second semiconductor devices 400 may be disposed on both sides of the first semiconductor device 300 in the X-direction, but example embodiments are not limited thereto. Accordingly, the semiconductor-bridges 500 may be disposed on both sides of the first semiconductor device 300 in the X-direction. For example, the semiconductor-bridges 500 may include a first semiconductor-bridge 500-1 on the left and a second semiconductor-bridge 500-2 on the right in the X-direction. The first semiconductor-bridge 500-1 may overlap (for example, at least partially overlap) with portions of second semiconductor devices 400-1 and 400-3 on the left and a left portion of the first semiconductor device 300. In some example embodiments, the second semiconductor-bridge 500-2 may additionally or alternatively overlap (for example, at least partially overlap) with portions of the second semiconductor devices 400-2 and 400-4 on the right and a right portion of the first semiconductor device 300. The first semiconductor-bridge 500-1 and the second semiconductor-bridge 500-2 may be positioned symmetrically in the X-direction and may be symmetrically connected to the left second semiconductor device 400 and the right second semiconductor device 400, respectively, but example embodiments are not limited thereto. Accordingly, hereinafter, for convenience, the first semiconductor-bridge 500-1, and the through electrodes 240, portions of the upper redistribution layer 210, and the second connection terminals 350 which are connected thereto are described.

The first semiconductor-bridge 500-1 may be stacked on the lower redistribution layer 220 through an adhesive layer 550. In some example embodiments, the body layer 201 is maintained thin between the first semiconductor-bridge 500-1 and the lower redistribution layer 220, and the first semiconductor-bridge 500-1 may be stacked on the body layer 201 through (for example, by) the adhesive layer 550.

The first semiconductor-bridge 500-1 may include a bridge body 501, wires 510, a decoupling capacitor 520, and pads 530. The bridge body 501 may include, for example, Si, but example embodiments are not limited thereto. The wires 510 may be positioned in the bridge body 501. The pads 530 may be positioned in an upper portion of the bridge body 501. The wires 510 may be connected to the upper redistribution layer 210 through the pads 530 and the through electrodes 240 in the body layer 201. In some example embodiments, the pads 530 may be omitted, and the wires 510 may be directly connected to the upper redistribution layer 210 through (for example, by) the through electrodes 240.

The decoupling capacitor 520 may be positioned in the bridge body 501. The decoupling capacitor 520 may be connected to the upper redistribution layer 210 through (for example, by) the wires 510, the pads 530, and the through electrodes 240. In addition, or alternatively, the decoupling capacitor 520 may be connected to the first semiconductor device 300 through the upper redistribution lines 214 of the upper redistribution layer 210.

In more detail, according to some example embodiments a first redistribution line 214-1 included in the upper redistribution lines 214 of the upper redistribution layer 210 may extend from a position corresponding to the first semiconductor-bridge 500-1 in the X-direction to a position corresponding to the center of the first semiconductor device 300. In addition, or alternatively, the first redistribution line 214-1 may be connected to the decoupling capacitor 520 through the upper vertical vias 216, on the left in the X-direction. In addition, or alternatively, the first redistribution line 214-1 may be connected to the second connection terminal 350 positioned in a central portion of the first semiconductor device 300 in the X-direction through (for example, by) the upper vertical via 216, on the right in the X-direction. The second connection terminal 350 positioned in the central portion of the first semiconductor device 300 may correspond to a connection terminal for supplying power to the first semiconductor device 300. Hereinafter, the second connection terminal 350 positioned in the central portion of the first semiconductor device 300 and supplying power to the first semiconductor device 300 is referred to as a power connection terminal 350.

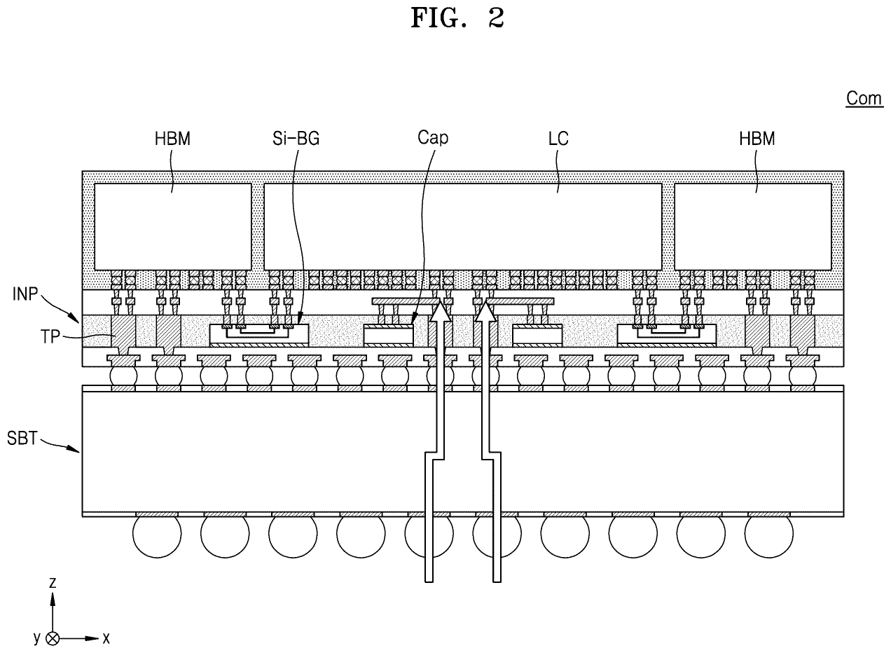

Accordingly, in the semiconductor package 1000 according to some example embodiments, the decoupling capacitor 520 of the first semiconductor-bridge 500-1 in the interposer 200 may be connected to the first semiconductor device 300 through (for example, by) the first redistribution line 214-1 of the upper redistribution layer 210 and the power connection terminal 350. As the decoupling capacitor 520 of the first semiconductor-bridge 500-1 is connected to the first semiconductor device 300 through the first redistribution line 214-1 extending in the X-direction, the power integrity (PI) characteristics of the first semiconductor device 300, e.g., a logic chip, may be improved while the reliability of the semiconductor package 1000 is maintained or substantially maintained. The reliability of the semiconductor package 1000 and the PI characteristics of the first semiconductor device 300 are described in more detail in the description of the comparative example of FIG. 2.

The circuit diagram of FIG. 1D schematically shows the impedance on a power path from the PMIC to the first semiconductor device 300, for example, the logic chip. However, for convenience, the capacitance is omitted, and the resistance and the inductance are only shown. For reference, in FIG. 1B, a thick arrow indicates a power path from the PMIC to the first semiconductor device 300. The PMIC, which may be a chip for controlling power supplied to the first semiconductor device 300 and the second semiconductor device 400, may be mounted on a main board together with the semiconductor package 1000, but example embodiments are not limited thereto. A logic chip LC may, for example, correspond to the first semiconductor device 300.

In the circuit diagram of FIG. 1D, R_{BRD} and L_{BRD} may refer to resistance and inductance of the main board (not shown), R_{SBT} and L_{SBT} may refer to resistance and inductance of the package substrate 100, and R_{INP} and L_{INP} may refer to resistance and inductance of the interposer 200. R_{INP2} and L_{INP2} in a dashed square portion may refer to resistance and inductance on a path of the interposer 200 connected to the decoupling capacitor Cap_{DE}. The decoupling capacitor Cap_{DE} may generally remove (for example, reduce) noise in the process of supplying power to the logic chip LC. Accordingly, when the capacitance of the decoupling capacitor Cap_{DE} is constant, the lower the impedance on the path, the better the noise removal performance. For example, the lower each of the resistance R_{INP2} and the inductance L_{INP2}, the better the noise removal performance of the decoupling capacitor Cap_{DE}.

FIG. 2 is a cross-sectional view of a semiconductor package according to a comparative example.

Referring to FIG. 2, in the case of a semiconductor package Com of the comparative example, a decoupling capacitor (not shown) in a silicon bridge Si-BG may be connected to the logic chip LC through (for example, by) a connection terminal positioned in a portion of the logic chip LC overlapping with the silicon bridge Si-BG. In the semiconductor package Com of the comparative example, the PI characteristics of the logic chip LC may be poor in a region where the silicon bridge Si-BG is not arranged, for example, in a region that does not overlap with the silicon bridge Si-BG.

To improve the PI characteristics of the logic chip LC in the region where the silicon bridge Si-BG is not arranged, individual capacitors Cap may be positioned in the body layer 201 of the interposer 200, as in the semiconductor package Com of the comparative example of FIG. 2. However, when many individual capacitors Cap are positioned in the body layer 201 of the interposer 200, reliability issues of the semiconductor package may be raised. The reliability issues may include, for example, the weakened support force of the interposer INP and a lack or substantial lack of signal paths, caused when the number of through posts decreases as the number of individual capacitors Cap increases.

On the contrary, in the semiconductor package 1000 according to some example embodiments, the decoupling capacitor 520 of the semiconductor-bridge 500 in the interposer 200 may be connected to the first semiconductor device 300 through (for example by) the first redistribution lines 214-1 and 214-2 of the upper redistribution layer 210 and the power connection terminals 350. The first redistribution lines 214-1 and 214-2 may extend from a position corresponding to the semiconductor-bridge 500 to the power connection terminal 350 positioned in a center portion of the first semiconductor device 300 in the X-direction. As such, since the decoupling capacitor 520 of the semiconductor-bridge 500 is connected to the first semiconductor device 300 through (for example, by) the first redistribution lines 214-1 and 214-2 extending in the X-direction, the PI characteristics of the first semiconductor device 300, for example, the logic chip, may be improved while the reliability of the semiconductor package 1000 is maintained. For example, since the first redistribution lines 214-1 and 214-2 may cover a region where the semiconductor-bridges 500 are not arranged, separate individual capacitors are not needed. Accordingly, the reliability of the semiconductor package 1000 may be maintained by addressing the problems, such as the weakened support force of the interposer 200 and lack or substantial lack of the signal paths, due to the decreased number of through posts. In addition, as the first redistribution lines 214-1 and 214-2 replace the operation of the individual capacitors Cap of the semiconductor package Com of the comparative example, the PI characteristics of the first semiconductor device 300 in a region where the semiconductor-bridges 500 are not arranged may be improved.

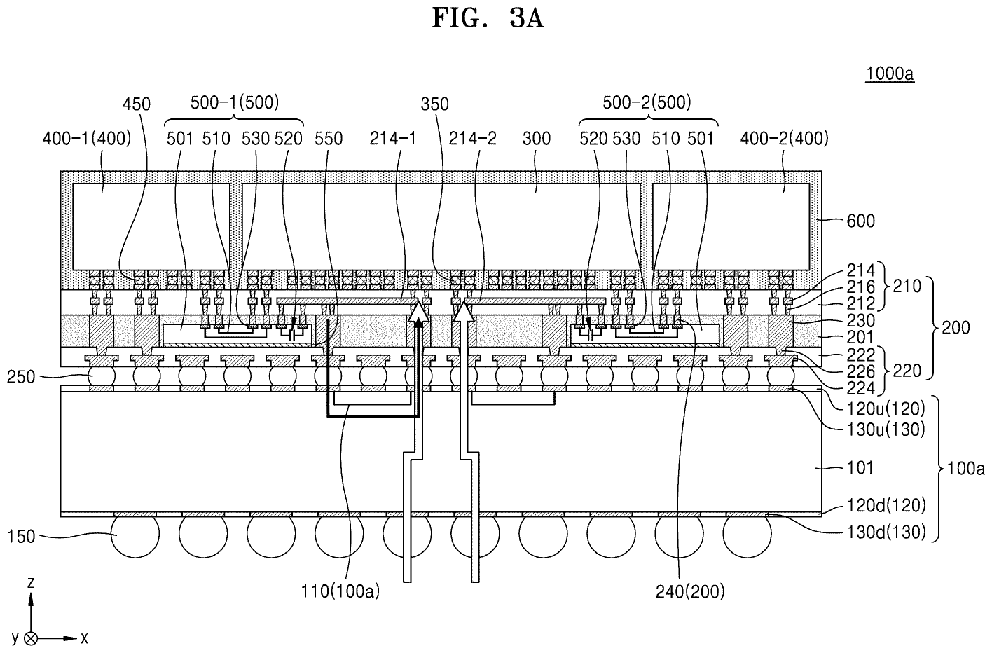

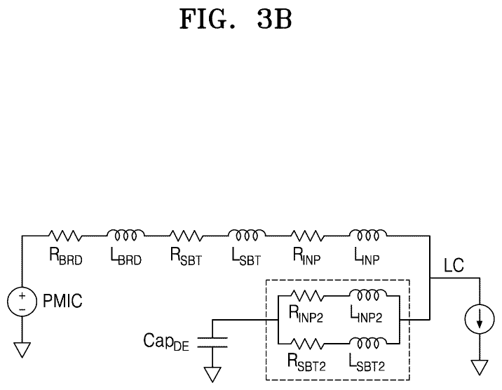

FIG. 3A is a cross-sectional view of a semiconductor package according to some example embodiments, and FIG. 3B is a schematic cross-sectional view showing the impedance on the power path from the PMIC to the logic chip in the semiconductor package of FIG. 3A. For convenience, the descriptions already given with reference to FIGS. 1A to 2 are briefly given or omitted.

Referring to FIGS. 3A and 3B, a semiconductor package 1000a according to some example embodiments may be different from the semiconductor package 1000 of FIG. 1B in that the semiconductor package 1000a further includes an additional path from the decoupling capacitor 520 of the semiconductor-bridge 500 to the power connection terminals 350 of the first semiconductor device 300. For example, the semiconductor package 1000a according to some example embodiments may include a package substrate 100a, an interposer 200, a first semiconductor device 300, second semiconductor devices 400, semiconductor-bridges 500, and a sealant 600. The interposer 200, the first semiconductor device 300, the second semiconductor devices 400, the semiconductor-bridges 500, and the sealant 600 may correspond to or be similar to those in the semiconductor package 1000 of FIG. 1B.

In the semiconductor package 1000a according to some example embodiments, the package substrate 100a may include a substrate body layer 101, and a first wire 110 in the substrate body layer 101 may form an additional path from the decoupling capacitor 520 to the power connection terminals 350 of the first semiconductor device 300. For example, the substrate body layer 101 of the package substrate 100a may include multi-layer wires, and the first wire 110 may correspond to the uppermost wire among the multi-layer wires. The first wire 110 may be connected to the upper substrate pads 130u.

The first redistribution line 214-1 may be connected to the through posts 230 through (for example, by) the upper vertical vias 216, and the through posts 230 may be connected to the first connection terminals 250 on the upper substrate pads 130u through (for example, by) the lower redistribution layer 220. Accordingly, as can be seen from the black solid arrow, the decoupling capacitor 520 may be connected to the power connection terminals 350 via (for example, by) the through posts 230, the lower redistribution layer 220, the first connection terminals 250, and the first wire 110.

When a path using the first redistribution line 214-1 is referred to as a first path and a path additionally using (for example, defined or at least partially defined by) the through posts 230, the lower redistribution layer 220, the first connection terminals 250, and the first wire 110 is referred as a second path, the first path may be, for example, connected in parallel to the second path between the decoupling capacitor 520 and the first semiconductor device 300.

The circuit diagram of FIG. 3B schematically shows the impedance on the power path from the PMIC to the first semiconductor device 300, e.g., the logic chip, in the semiconductor package 1000a according to some example embodiments. The dashed square portion shows the impedance of the path between the decoupling capacitor 520 and the first semiconductor device 300, and R_{SBT2} and L_{SBT2} may refer to resistance and inductance on the additional path, e.g., the second path. For reference, R_{SBT2} and L_{SBT2} may include not only resistance and inductance of the first wire 110 of the package substrate 100, but also resistance and inductance of the path between the first redistribution line 214-1 and the first wire 110.

As shown in the circuit diagram of FIG. 3B, R_{INP2} and L_{INP2} of the first path may be positioned in parallel or substantially in parallel to R_{SBT2} and the L_{SBT2} of the second path. Accordingly, the total resistance Rₜₒₜ and the total inductance Lₜₒₜ may be calculated as follows:

Rₜₒₜ=R_{INP2}//R_{SBT2},Lₜₒₜ=R_{INP2}//R_{SBT2}

Accordingly, the total resistance Rₜₒₜ is less than R_{INP2} of the first path, and the total inductance Lₜₒₜ is less than L_{INP2} of the first path. As described above, when the capacitance of the decoupling capacitor Cap_{DE} is constant, the lower the impedance on the path, the higher the noise removal performance. Accordingly, in the semiconductor package 1000a according to some example embodiments, the noise removal performance may be improved and the power distribution network (PDN) performance may also be improved as an additional path is provided between the decoupling capacitor 520 and the first semiconductor device 300.

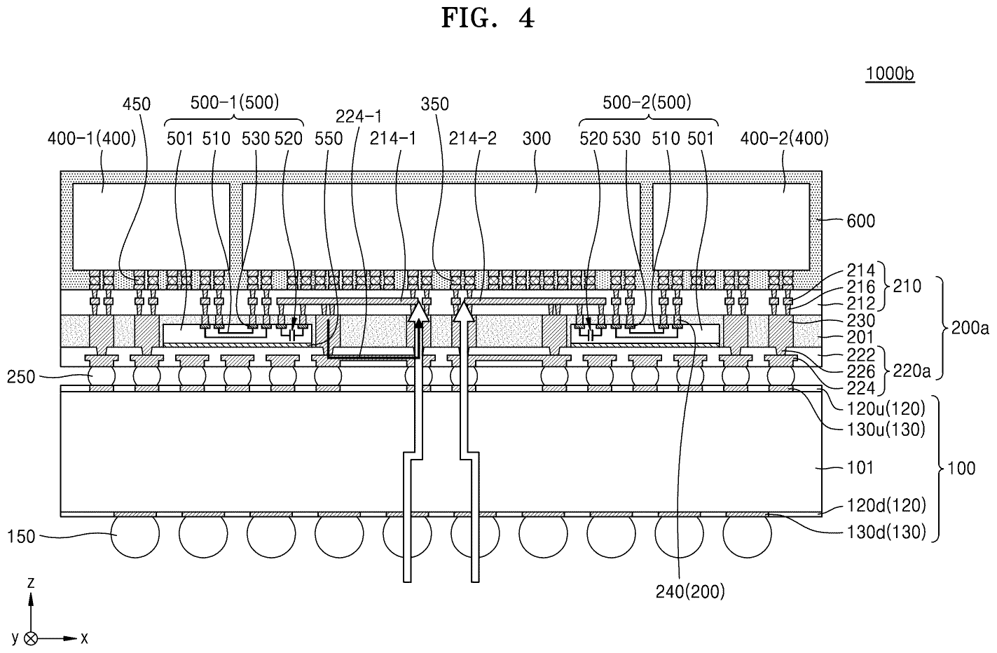

FIG. 4 is a cross-sectional view of a semiconductor package according to some example embodiments. The descriptions already given with reference to FIGS. 1A to 3B are briefly given or omitted.

Referring to FIG. 4, a semiconductor package 1000b according to some example embodiments may be similar to the semiconductor package 1000a of FIG. 3A in that the semiconductor package 1000b further includes an additional path from the decoupling capacitor 520 of the semiconductor-bridge 500 to the power connection terminals 350 of the first semiconductor device 300. However, the semiconductor package 1000b may be different from the semiconductor package 1000a of FIG. 3A in that an additional path may be implemented using a lower redistribution layer 220a. More specifically, the semiconductor package 1000b according to some example embodiments may include a package substrate 100, an interposer 200a, a first semiconductor device 300, second semiconductor devices 400, semiconductor-bridges 500, and a sealant 600. The package substrate 100, the first semiconductor device 300, the second semiconductor devices 400, the semiconductor-bridges 500, and the sealant 600 may correspond to or be similar to those of the semiconductor package 1000 of FIG. 1B.

In the semiconductor package 1000b according to some example embodiments, the interposer 200a may include the lower redistribution layer 220a, and a second redistribution line 224-1 of the lower redistribution layer 220a may form an additional path from the decoupling capacitor 520 to the power connection terminals 350 of the first semiconductor device 300. For example, the first redistribution line 214-1 may be connected to the through posts 230 through the upper vertical vias 216, and the through posts 230 may be connected to the second redistribution line 224-1 of the lower redistribution layer 220a. Accordingly, as can be seen from the black solid arrow, the decoupling capacitor 520 may be connected to the power connection terminals 350 via (for example, by) the through posts 230 and the second redistribution line 224-1.

When a path using the first redistribution line 214-1 is referred to as a first path and a path additionally using the through posts 230 and the second redistribution line 224-1 is referred to as a second path, the first path may be connected in parallel to the second path between the decoupling capacitor 520 and the first semiconductor device 300.

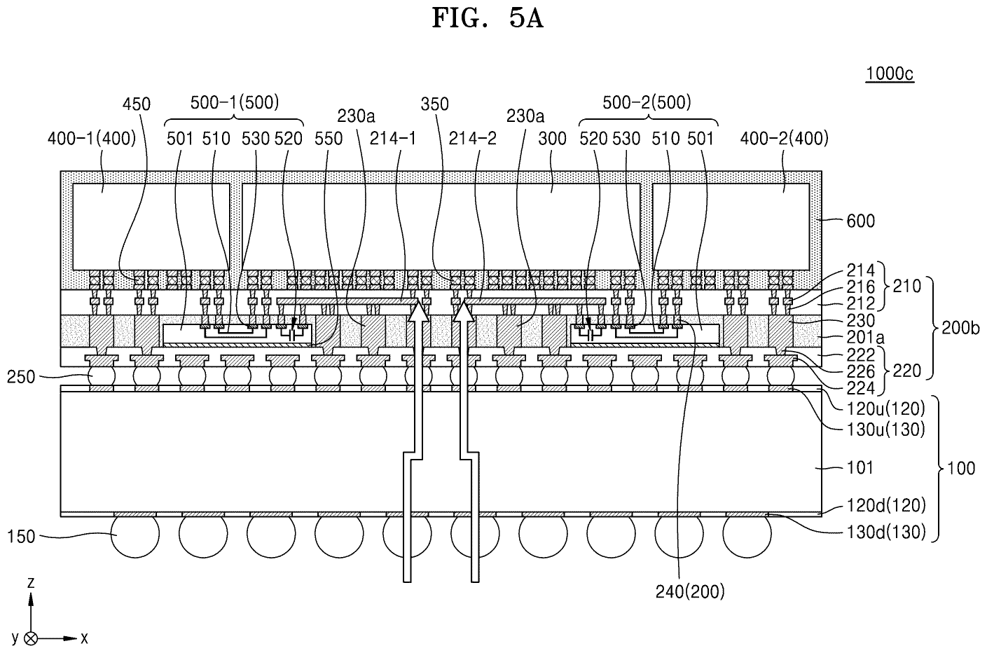

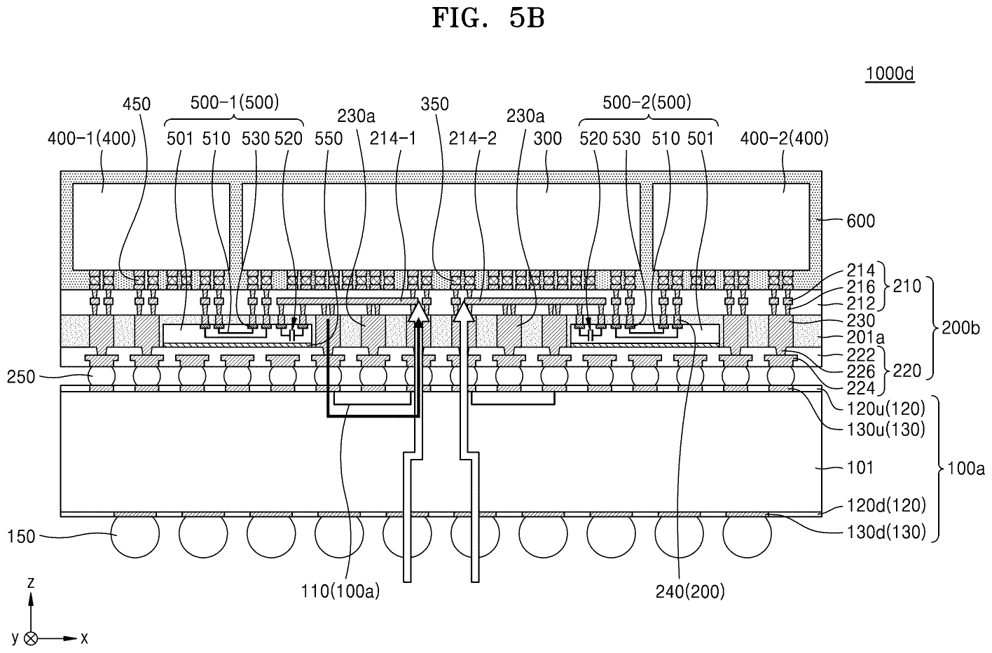

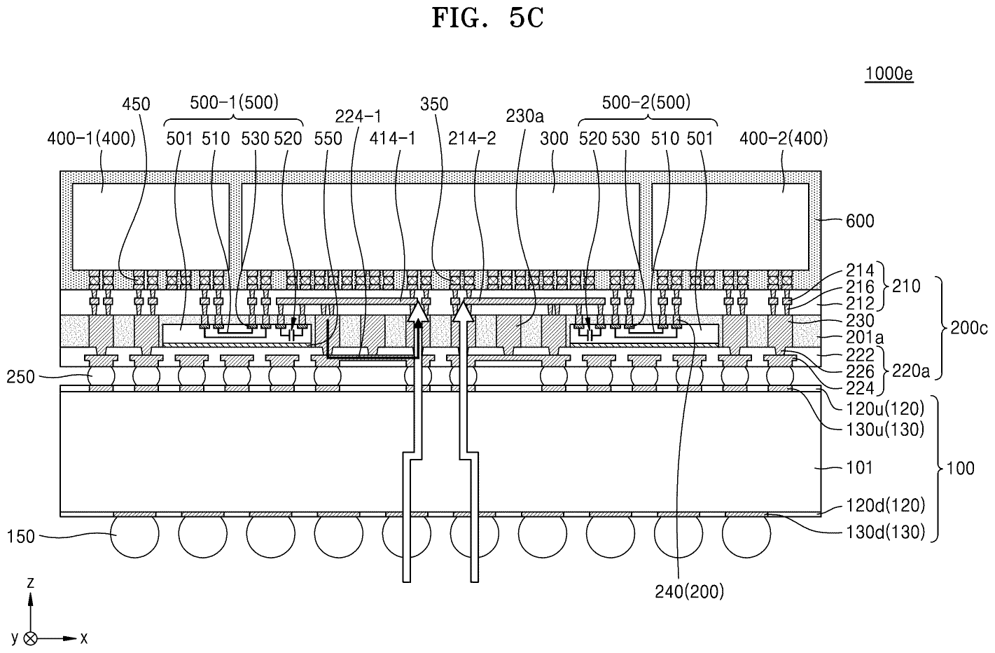

FIGS. 5A to 5C are cross-sectional views of a semiconductor package according to some example embodiments. For the sake of conciseness, the descriptions already given with reference to FIGS. 1A to 4 are briefly given or omitted.

Referring to FIG. 5A, a semiconductor package 1000c according to some example embodiments may be slightly different from the semiconductor package 1000 of FIG. 1B in that, for example, an interposer 200b further includes additional through posts 230a. For example, in the semiconductor package 1000c according to some example embodiments, the interposer 200b may further include the additional through posts 230a positioned in a body layer 201a. For example, in the semiconductor package Com of the comparative example, the additional through posts 230a may be positioned in a portion where the individual capacitor Cap has been placed, and/or a portion where a gap between the through posts 230 is wide. As described above, by placing additional through posts 230a in the body layer 201a of the interposer 200b, the physical support force of the interposer 200b may be strengthened. In addition, or alternatively, the additional through-posts 230a may be used, for example, signal paths, thereby addressing a lack or limited number of of signal paths. Accordingly, the reliability issues of the semiconductor package 1000c may be resolved or reduced.

Referring to FIG. 5B, a semiconductor package 1000d according to some example embodiments may be slightly different from the semiconductor package 1000a of FIG. 3A in that an interposer 200b further includes additional through posts 230a. For example, in the semiconductor package 1000d according to some example embodiments, the interposer 200b may further include the additional through posts 230a positioned in the body layer 201a. The additional through posts 230a may correspond to or be similar to those in the semiconductor package 1000c of FIG. 5A

Referring to FIG. 5C, a semiconductor package 1000e according to some example embodiments may be slightly different from the semiconductor package 1000b of FIG. 4 in that, for example, an interposer 200c may further include additional through posts 230a. Specifically, in the semiconductor package 1000e according to some example embodiments, the interposer 200c may further include the additional through posts 230a positioned in the body layer 201a. The additional through posts 230a may correspond to or be similar to those in the semiconductor package 1000c of FIG. 5A.

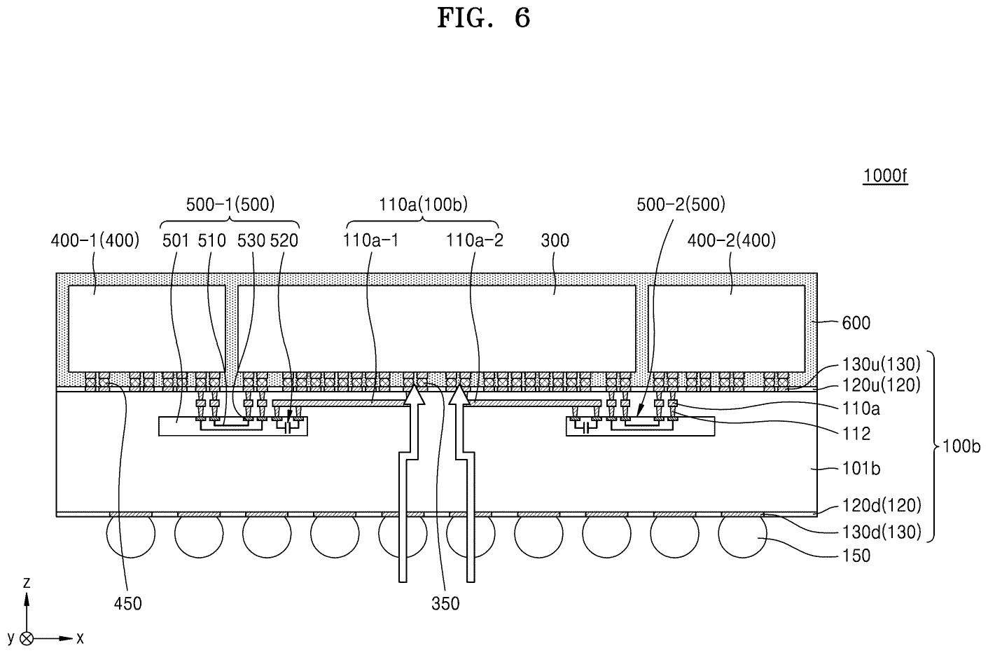

FIG. 6 is a cross-sectional view of a semiconductor package according to some example embodiments. The descriptions already given with reference to FIGS. 1A to 5C are briefly given or omitted.

Referring to FIG. 6, a semiconductor package 1000f according to some example embodiments may be different from the semiconductor packages 1000, 1000a to 1000e of FIGS. 1B, 3A, 4, and 5A to 5C in that, for example, the semiconductor package 1000f may not include an interposer and the semiconductor-bridges 500 may positioned in the package substrate 100b. For example, the semiconductor package 1000f according to some example embodiments may include a package substrate 100b, a first semiconductor device 300, second semiconductor devices 400, semiconductor-bridges 500, and a sealant 600. The first semiconductor device 300, the second semiconductor devices 400, the semiconductor-bridges 500, and the sealant 600 may correspond to or be similar to those in the semiconductor package 1000 of FIG. 1B.

The package substrate 100b may include a substrate body layer 101b, protective layers 120, and substrate pads 130. The semiconductor-bridges 500 may be, for example, positioned in the substrate body layer 101b. In addition, or alternatively, the wires 510 and the decoupling capacitor 520 of the semiconductor-bridge 500 may be connected to the first semiconductor device 300 through (for example, by) first wires 110a-1 and 110a-2 of the multi-layer wires 110a of the substrate body layer 101. For example, the substrate body layer 101b of the package substrate 100b may include the multi-layer wires 110a, and the first wires 110a-1 and 110a-2 may correspond to uppermost wires among the multi-layer wires 110a. The first wires 110a-1 and 110a-2 may be connected to the upper substrate pads 130u through (for example, by) vertical vias 112. In addition, or alternatively, the first wires 110a-1 and 110a-2 may be connected to the first semiconductor device 300 through the (for example, by) power connection terminals 350.

As shown in FIG. 6, the first wires 110a-1 and 110a-2 may extend in the X-direction in the substrate body layer 101b of the package substrate 100b. For example, the first wire 110a-1 on the left may extend to the right from a position corresponding to the first semiconductor-bridge 500-1 in a first direction to a central portion of the first semiconductor device 300 where the power connection terminals 350 are arranged. In addition, the first wire 110a-2 on the right may extend to the left from a position corresponding to the second semiconductor-bridge 500-2 in the first direction to the center portion of the first semiconductor device 300 where the power connection terminals 350 are arranged.

For reference, the semiconductor package 1000f according to some example embodiments may correspond to a 2.1D package. The 2.1D package may not include an interposer, unlike, e.g., a 2.3D package or a 2.5D package that includes an interposer. In addition, unlike the 2.3D package, the semiconductor-bridges 500 may be positioned in the package substrate 100b. The first semiconductor device 300 and the second semiconductor device 400 may be directly stacked on the package substrate 100b through (for example, by) the second connection terminals 350 and the third connection terminals 450 which are relatively small. Accordingly, the size of the upper substrate pads 130u of the package substrate 100b may be relatively small, but example embodiments are not limited thereto.

In the semiconductor package 1000f according to some example embodiments, the semiconductor-bridges 500 may be positioned in the package substrate 100b, and the decoupling capacitor 520 of the semiconductor-bridge 500 may be connected to the first semiconductor device 300 through (for example, by) the first wires 110a-1 and 110a-2 of the substrate body layer 101b of the package substrate 100b. As described above, since the decoupling capacitor 520 of the semiconductor-bridge 500 is connected to the first semiconductor device 300 through (for example, by) the first wires 110a-1 and 110a-2 extending in the X-direction, the PI characteristics of the first semiconductor device 300, for example, the logic chip, may be improved while the reliability of the semiconductor package 1000f is maintained or substantially maintained. For example, by covering or at least partially covering the region where the semiconductor-bridges 500 are not arranged and replacing the operation of the individual capacitors, the first wires 110a-1 and 110a-2 may improve the PI characteristics of the first semiconductor device 300 in the region where the semiconductor-bridges 500 are not arranged.

While inventive concepts have been particularly shown and described with reference to embodiments thereof, it will be understood by one of ordinary skill in the art that various changes in form and details may be made therein without departing from the spirit and scope of the following claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package, comprising:
a package substrate;
an interposer on the package substrate and comprising a body layer and a redistribution layer;
a semiconductor-bridge in the interposer and comprising a decoupling capacitor;
a first semiconductor device on a central portion of a top surface of the interposer; and
a second semiconductor device on an outer portion of the top surface of the interposer and adjacent to the first semiconductor device,
wherein the decoupling capacitor is connected to the first semiconductor device by the redistribution layer.

2. The semiconductor package of claim 1, wherein the second semiconductor device is adjacent to a side surface of the first semiconductor device in a first direction,
the semiconductor-bridge overlaps with
at least a portion of the first semiconductor device, and
at least a portion of the second semiconductor device, and
the decoupling capacitor is connected to a connection terminal, the connection terminal in a central portion of the first semiconductor device in the first direction by the redistribution layer, the redistribution layer extending in the first direction.

3. The semiconductor package of claim 1, wherein the redistribution layer comprises an upper redistribution layer and a lower redistribution layer, the upper redistribution layer being on a top surface of the body layer and the lower redistribution layer being on a bottom surface of the body layer,
the semiconductor-bridge is in the body layer, and
the decoupling capacitor is connected to the first semiconductor device by the upper redistribution layer.

4. The semiconductor package of claim 3, wherein the upper redistribution layer is connected to the lower redistribution layer by a Cu post, the Cu post at least partially extending through the body layer, and
the decoupling capacitor is connected to the first semiconductor device by
the upper redistribution layer,
the Cu post,
the lower redistribution layer, and
a wiring layer of the package substrate.

5. The semiconductor package of claim 4, wherein a path by which the decoupling capacitor is connected to the first semiconductor device and at least partially defined by the upper redistribution layer is a first path,
a path by which the decoupling capacitor is connected to the first semiconductor device and at least partially defined by the upper redistribution layer, the Cu post, the lower redistribution layer, and the wiring layer of the package substrate is a second path, and
the first path is connected in parallel to the second path between the decoupling capacitor and the first semiconductor device.

6. The semiconductor package of claim 1, wherein the first semiconductor device includes a logic chip, and the second semiconductor device includes at least one of a memory chip or a memory package.

7. The semiconductor package of claim 6, wherein the second semiconductor device includes a high bandwidth memory (HBM) package.

8. The semiconductor package of claim 1, wherein the semiconductor-bridge includes a silicon (Si)-bridge, and the first semiconductor device is connected to the second semiconductor device by internal wiring of the semiconductor-bridge.

9. The semiconductor package of claim 1, wherein the interposer does not comprise a separate capacitor therein.

10. A semiconductor package comprising:
a package substrate;
a panel level package (PLP) interposer on the package substrate and comprising a body layer and a redistribution layer;
a silicon (Si)-bridge in the PLP interposer and comprising at least one decoupling capacitor;
a logic chip on a central portion of a top surface of the PLP interposer; and
at least two high bandwidth memory (HBM) packages on an outer portion of the top surface of the PLP interposer and adjacent to sides of the logic chip in a first direction,
wherein the at least one decoupling capacitor is connected to the logic chip by the redistribution layer and a connection terminal, the redistribution layer extending in the first direction, and the connection terminal being in a central portion of the logic chip in the first direction.

11. The semiconductor package of claim 10, wherein the at least two HBM packages comprise a first HBM package on a left side of the logic chip and a second HBM package on a right side of the logic chip in the first direction,
the Si-bridge comprises a first Si-bridge and a second Si-bridge, the first Si-bridge including a decoupling capacitor of the at least one decoupling capacitor and at least partially overlapping with a portion of the first HBM package and with a left portion of the logic chip in the first direction, the second Si-bridge including a decoupling capacitor of the at least one decoupling capacitor and at least partially overlapping with a portion of the second HBM package and with a right portion of the logic chip in the first direction,
the decoupling capacitor of the first Si-bridge is connected to the logic chip by a first redistribution line of the redistribution layer, the first redistribution line extending in the first direction from a position corresponding to the first Si-bridge to a position corresponding to a central portion of the logic chip, and
the decoupling capacitor of the second Si-bridge is connected to the logic chip by a second redistribution line of the redistribution layer, the second redistribution line extending in the first direction from a position corresponding to the second Si-bridge to a position corresponding to a central portion of the logic chip.

12. The semiconductor package of claim 10, wherein a path connecting the decoupling capacitor to the logic chip and at least partially defined by the redistribution layer comprises a first path, and further comprises a second path connected in parallel to the first path and connecting the decoupling capacitor to the logic chip.

13. The semiconductor package of claim 10, wherein the redistribution layer comprises an upper redistribution layer and a lower redistribution layer, the upper redistribution layer on a top surface of the body layer and the lower redistribution layer on a bottom surface of the body layer,
the Si-bridge is in the body layer, and
the decoupling capacitor is connected to the logic chip by the upper redistribution layer.

14. The semiconductor package of claim 13, wherein the upper redistribution layer is connected to the lower redistribution layer by a Cu post, the Cu post at least partially extending through the body layer, and
the decoupling capacitor is connected to the logic chip by an additional path, the additional path at least partially defined by the upper redistribution layer, the Cu post, the lower redistribution layer, and a wiring layer of the package substrate.

15. A semiconductor package comprising:
a package substrate;
a silicon (Si)-bridge in or on the package substrate and comprising a decoupling capacitor;
a logic chip on a central portion of the package substrate; and
a high bandwidth memory (HBM) package on an outer portion of the package substrate and adjacent to the logic chip in a first direction,
wherein the decoupling capacitor is connected to the logic chip by a wiring layer of the package substrate or by a redistribution layer on the package substrate.

16. The semiconductor package of claim 15, wherein the Si-bridge is in the package substrate and at least partially overlaps with a portion of the logic chip and with a portion of the HBM package, and
the decoupling capacitor is connected to a connection terminal by a wiring layer of the package substrate, the connection terminal positioned in a central portion of the logic chip in the first direction and the wiring layer extending in the first direction.

17. The semiconductor package of claim 15, further comprising a panel level package (PLP) interposer on the package substrate and comprising a body layer and a redistribution layer,
wherein the logic chip and the HBM package are on a top surface of the PLP interposer,
the Si-bridge is in the PLP interposer, and
the decoupling capacitor is connected to the logic chip by the redistribution layer.

18. The semiconductor package of claim 17, wherein the Si-bridge at least partially overlaps with a portion of the logic chip and with a portion of the HBM package, and
the decoupling capacitor is connected to a connection terminal by the redistribution layer, the connection terminal in a central portion of the logic chip in the first direction and the redistribution layer extending in the first direction.

19. The semiconductor package of claim 17, wherein a path connecting the decoupling capacitor to the logic chip and at least partially defined by the redistribution layer comprises a first path, and further comprises a second path, the second path connected in parallel to the first path and connecting the decoupling capacitor to the logic chip.

20. The semiconductor package of claim 19, wherein the redistribution layer comprises an upper redistribution layer and a lower redistribution layer, the upper redistribution layer on a top surface of the body layer and the lower redistribution layer on a bottom surface of the body layer,
the upper redistribution layer is connected to the lower redistribution layer by a Cu post, the Cu post at least partially extending through the body layer,
the first path is at least partially defined by the upper redistribution layer, and
the second path is defined by the upper redistribution layer, the Cu post, the lower redistribution layer, and the wiring layer of the package substrate.
